(19) United States
(12) Patent Application Publication
(10) Pub. No.: US 2024/0186324 A1
(43) Pub. Date: Jun. 6, 2024

(54) LATCH CROSS COUPLE FOR STACKED AND STEPPED FET

(71) Applicant: INTERNATIONAL BUSINESS MACHINES CORPORATION, Armonk, NY (US)

(72) Inventors: Albert M. Chu, Nashua, NH (US); Junli Wang, Slingerlands, NY (US); Jay William Strane, Warwick, NY (US)

(21) Appl. No.: 18/061,526

(22) Filed: Dec. 5, 2022

(51) Int. Cl. H01L 27/092; H01L 29/423

(52) U.S. Cl. CPC H01L 27/0922; H01L 29/42324; H01L 29/42356; H03K 3/356104

(57) ABSTRACT

A semiconductor structure is presented having a first field effect transistor (FET) including a first device layer, a second FET including a second device layer, where the first device layer has a stepped portion with respect to the second device layer, and an electrical connection between a gate of the first FET and a gate of the second FET at the stepped portion of the first device layer. The first FET is stacked over the second FET. The second device layer is larger than the first device layer. The gate of the first FET is positioned above the first device layer having a stepped portion.

### BACKGROUND

The present invention relates generally to semiconductor devices, and more specifically, to constructing a latch cross couple for stacked and stepped field effect transistors (FETs).

Semiconductor devices are used in a variety of electronic applications, such as personal computers, cell phones, digital cameras, and other electronic equipment. Semiconductor devices are usually fabricated by sequentially depositing insulating or dielectric layers, conductive layers, and semiconductive layers of material over a semiconductor substrate, and patterning the various material layers using lithography to form circuit components and elements thereon.

The semiconductor industry has experienced rapid growth due to improvements in the integration density of a variety of electronic components (e.g., transistors, diodes, resistors, capacitors, etc.). For the most part, this improvement in integration density has come from shrinking the semiconductor process node. With the increased demands for miniaturization, higher speed, greater bandwidth, lower power consumption, and lower latency, chip layout has become more complicated and difficult to achieve in the production of semiconductor dies.

Device structures for a field-effect transistor (FET) generally include a source, a drain, and a gate electrode configured to switch carrier flow in a channel formed in a semiconductor body between the source and drain. When a control voltage exceeding a designated threshold voltage is applied to the gate electrode, the flow of carriers in the channel between the source and drain produces a device output current.

The body and channel of a planar FET are arranged beneath the top surface of a substrate on which the gate electrode is supported. A fin-type field-effect transistor (FinFET) is a non-planar device structure for a FET that may be more densely packed in an integrated circuit than planar FETs. A FinFET includes a fin, heavily-doped source/drain regions, and a gate electrode that wraps around the fin. During operation, a channel for carrier flow is formed in the fin between the source/drain regions. In comparison with planar FETs, the arrangement between the gate structure and fin improves control over the channel and reduces the leakage current when the FinFET is in its “Off” state. This, in turn, lowers threshold voltages in comparison with planar FETs, and results in improved performance and lowered power consumption.

Nanosheet FETs have been developed as an advanced type of FinFET that may permit additional increases in packing density in an integrated circuit (IC). The body of a nanosheet FET includes multiple nanosheet channel layers vertically stacked in a three-dimensional array. Sections of a gate stack may surround all sides of the individual nanosheet channel layers in a gate-all-around arrangement. The nanosheet channel layers are initially arranged in a layer stack with sacrificial layers composed of a material (e.g., silicon-germanium) that can be etched selectively to the material (e.g., silicon) constituting the nanosheet channel layers. The sacrificial layers are etched and removed in order to release the nanosheet channel layers, and to provide spaces for the formation of the gate stack.

Gate-all-around field effect transistors (GAAFETs) (e.g., nanowire-type GAAFETs or nanosheet-type GAAFETs) have been developed in order to improve drive current and electrostatics and to allow for device size scaling, increased device density and reduced area consumption. A GAAFET includes elongated nanoshape(s) (e.g., nanowire(s) or nanosheet(s)), which extend laterally between source/drain regions, and a wrap-around gate structure, which wraps around the nanoshape(s) such that the nanoshape(s) function as channel region(s).

Recently, complementary field effect transistors (CFETs) have been developed in order to further increase on-chip device density and reduce area consumption. A CFET usually includes a pair of N-type and P-type GAAFETs that are stacked one above the other and that have a common gate structure as opposed to being positioned side by side with discrete gate structures. Specifically, a CFET includes an N-type GAAFET on one-level, a P-type GAAFET on an adjacent level (e.g., above or below) and, a common gate that extends vertically across and wraps around the stacked channel regions of the N-type and P-type GAAFETs. Usually, the source/drain regions of the lower-level GAAFET will be electrically isolated from the source/drain regions of the upper-level GAAFET by one or more isolation layers. Such CFETs can, for example, be incorporated into a six-transistor (6T) static random access memory (SRAM) cell, one for each pair of pull-down and pull-up field effect transistors, respectively. While using CFETs can increase on-chip device density and reduce area consumption, providing signal connections to the source/drain regions of the lower-level GAAFETs (e.g., to achieve the cross-couple connection in an SRAM cell) can be quite complex.

### SUMMARY

In accordance with an embodiment, a semiconductor structure is provided. The semiconductor structure includes a first field effect transistor (FET) including a first device layer, a second FET including a second device layer, where the first device layer has a stepped portion with respect to the second device layer, and an electrical connection between a gate of the first FET and a gate of the second FET at the stepped portion of the first device layer.

In accordance with another embodiment, a semiconductor structure is provided. The semiconductor structure includes a first field effect transistor (FET) including a first device layer, a second FET including a second device layer, and an electrical connection between a gate of the first FET and a gate of the second FET at the stepped portion of the first device layer.

In accordance with yet another embodiment, a semiconductor structure is provided. The semiconductor structure includes a first field effect transistor (FET) including a first device layer, a second FET including a second device layer, where the second device layer is larger than the first device layer, and an electrical connection between a gate of the first FET and a gate of the second FET at the stepped portion of the first device layer.

In one preferred aspect, the first FET is stacked over the second FET.

In another preferred aspect, the second device layer is larger than the first device layer.

In yet another preferred aspect, the first FET is a p-type FET and the second FET is an n-type FET.

In one preferred aspect, the gate of the first FET is positioned above the first device layer having a stepped portion.

In another preferred aspect, the gate of the first FET is positioned above both the first and second device layers.

In yet another preferred aspect, the second FET includes a floating gate.

In yet another preferred aspect, the floating gate is vertically aligned with the stepped portion of the first device layer.

In one preferred aspect, the first device layer is centered with respect to the second device layer.

In another preferred aspect, the first device layer is positioned adjacent the second device layer such that a surface of the first device layer is horizontally aligned with a surface of the second device layer.

In yet another preferred aspect, the first device layer generally overlaps the second device layer.

In yet another preferred aspect, the gate of the first FET is positioned above the first device layer having a doubled stepped configuration.

In yet another preferred aspect, the gate of the first FET is positioned above both the first and second device layers.

The advantages of the present invention include producing transistors that consume less power, have better performance, occupy less area on a wafer, and reduce cost in semiconductor manufacturing. The advantages of the present invention further include improving latch cross couple configurations or connections used in circuits. In conventional non-stacked transistors, a latch cross couple connects the PC or gate layer of an NFET to the PC or gate layer of the PFET such that a cross or “X” connection is established therebetween. This “X” connection between PC or gate layers of PFETs and NFETs however can be challenging. However, stacked FETs, as presented herein, where, e.g., the PFET is stacked over the NFET, can advantageously alleviate such implementation challenges. In addition to the PFETs and NFETs being stacked, they can also be advantageously stepped. The term “stepped” refers to a stepped structure where one nanosheet (or FET) is wider than the other nanosheet (or FET) to advantageously create a step or ledge. For example, the first nanosheet stack (or FET) is advantageously wider than the second nanosheet stack (or FET) such that a stepped region or ledge is advantageously formed at the intersection of the first and second nanosheet stacks (or FETs).

It should be noted that the exemplary embodiments are described with reference to different subject-matters. In particular, some embodiments are described with reference to method type claims whereas other embodiments have been described with reference to apparatus type claims. However, a person skilled in the art will gather from the above and the following description that, unless otherwise notified, in addition to any combination of features belonging to one type of subject-matter, also any combination between features relating to different subject-matters, in particular, between features of the method type claims, and features of the apparatus type claims, is considered as to be described within this document.

These and other features and advantages will become apparent from the following detailed description of illustrative embodiments thereof, which is to be read in connection with the accompanying drawings.

### BRIEF DESCRIPTION OF THE DRAWINGS

The invention will provide details in the following description of preferred embodiments with reference to the following figures wherein:

FIG. 1 is a circuit diagram of a stacked field effect transistor (FET), in accordance with an embodiment of the present invention;

FIG. 2 is a top view of a semiconductor structure where a stacked and stepped FET configuration is presented, in accordance with an embodiment of the present invention;

FIG. 3 is a cross-sectional view of the semiconductor structure of FIG. 2 depicting the first FET and the second FET of the stacked and stepped FET configuration, in accordance with an embodiment of the present invention;

FIG. 4 is the circuit diagram of the stacked FET, in accordance with an embodiment of the present invention;

FIG. 5 is a top view of a semiconductor structure where the top FET of the stacked and stepped FET configuration includes floating gates, in accordance with an embodiment of the present invention;

FIG. 6 is a cross-sectional view of the semiconductor structure of FIG. 5 depicting the floating gates of the top FET, in accordance with an embodiment of the present invention;

FIG. 7 is the circuit diagram of the stacked FET, in accordance with an embodiment of the present invention;

FIG. 8 is a top view of a semiconductor structure where the stacked and stepped FET configuration includes double step stacked FETs, in accordance with an embodiment of the present invention;

FIG. 9 is a cross-sectional view of the semiconductor structure of FIG. 8 depicting the first FET and the second FET of the stacked and stepped FET configuration, in accordance with an embodiment of the present invention;

FIG. 10 is the circuit diagram of the stacked FET, in accordance with an embodiment of the present invention;

FIG. 11 is a top view of a semiconductor structure where the stacked and stepped FET configuration includes double step stacked FETs with a smaller bottom transistor, in accordance with an embodiment of the present invention;

FIG. 12 is a cross-sectional view of the semiconductor structure of FIG. 11 depicting the first FET and the second FET of the stacked and stepped FET configuration with the smaller bottom FET, in accordance with an embodiment of the present invention;

FIG. 13 is the circuit diagram of the stacked FET, in accordance with an embodiment of the present invention;

FIG. 14 is a top view of a semiconductor structure where the stacked and stepped FET configuration includes double step stacked FETs with a larger bottom transistor, in accordance with an embodiment of the present invention; and

FIG. 15 is a cross-sectional view of the semiconductor structure of FIG. 14 depicting the first FET and the second FET of the stacked and stepped FET configuration with the larger bottom FET, in accordance with an embodiment of the present invention.

Throughout the drawings, same or similar reference numerals represent the same or similar elements.

### DETAILED DESCRIPTION

Embodiments in accordance with the present invention provide methods and devices for constructing a latch cross couple for a stacked and stepped field effect transistor (FET). The stacked FET includes a first device layer and a second device layer, where one of the device layers is advantageously shifted or tapered or stepped with respect to the other device layer. The shifted or tapered device layer is advantageously shifted or tapered between the device gates or “PC.” An electrical connection is advantageously made from the bottom gate to the top gate at the shifted or tapered device layer. A floating gate can also be employed over the shifted or tapered device layer. In other embodiments, a double step stacked FET is advantageously employed. Moreover, one of the device layers advantageously has a greater size or is larger than the other device layer.

Examples of semiconductor materials that can be used in forming such structures include silicon (Si), germanium (Ge), silicon germanium alloys (SiGe), silicon carbide (SIC), silicon germanium carbide (SiGeC), III-V compound semiconductors and/or II-VI compound semiconductors. III-V compound semiconductors are materials that include at least one element from Group III of the Periodic Table of Elements and at least one element from Group V of the Periodic Table of Elements. II-VI compound semiconductors are materials that include at least one element from Group II of the Periodic Table of Elements and at least one element from Group VI of the Periodic Table of Elements.

It is to be understood that the present invention will be described in terms of a given illustrative architecture; however, other architectures, structures, substrate materials and process features and steps/blocks can be varied within the scope of the present invention. It should be noted that certain features cannot be shown in all figures for the sake of clarity. This is not intended to be interpreted as a limitation of any particular embodiment, or illustration, or scope of the claims.

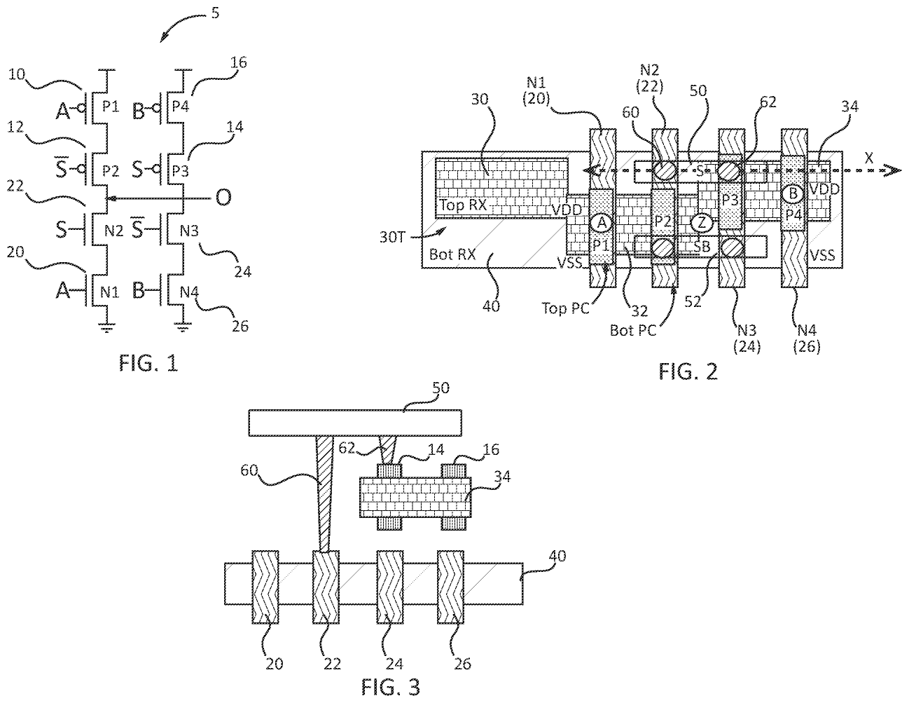

FIG. 1 is a circuit diagram of a stacked field effect transistor (FET), in accordance with an embodiment of the present invention.

The circuit 5 depicts an NFET circuit portion including a first NFET 20 (N1), a second NFET 22 (N2), a third NFET 24 (N3), and a fourth NFET 26 (N4). The circuit 5 further depicts a PFET circuit portion including a first PFET 10 (P1), a second PFET 12 (P2), a third PFET 14 (P3), and a fourth PFET 16 (P4). The PFET portion is stacked over the NFET portion. The PFET portion can be in a stepped relationship or tapered relationship with respect to the NFET portion.

FIG. 2 is a top view of a semiconductor structure where a stacked and stepped FET configuration is presented, in accordance with an embodiment of the present invention.

The top view depicts a top device layer 30T (Top Rx) having multiple sections 30, 32, 34 and a bottom device layer 40 (Bot Rx). The top device layer 30T can be referred to as a first device layer and the bottom device layer 40 can be referred to as a second device layer. The multiple sections 30, 32, 34 of the top device layer 30T can be advantageously shifted and/or tapered and/or offset from each other.

The p-type transistors are shown stacked over the n-type transistors. For example, the first PFET 10 (P1) is stacked over the first NFET 20 (N1), the second PFET 12 (P2) is stacked over the second NFET 22 (N2), the third NFET 24 (N3) is stacked over the third PFET 14 (P3), and the fourth NFET 26 (N4) is stacked over the fourth PFET 16 (P4). The device gates “top PC” and “bottom PC” are also shown. The shifted or tapered device layer is advantageously shifted or tapered between the device gates or “PC.” An electrical connection is advantageously made from the bottom gate to the top gate at the shifted or tapered device layer.

Letters “A” and “B” represent circuit input pins, whereas letter “Z” represents a circuit output pin. The circuit input pin 50 is represented as “S” and the circuit input pin 52 is represented as “SB.” “S” stands for “Select” and “SB” stands for “Select Bar.” The vias 60, 62 are shown connecting the circuit input pin 50 to the second NFET 22 (N2) and the third PFET 14 (P3).

As used herein, PC means shorter (<40 nanometer) gate Photolithography layer, CB means longer (>40 nanometer) gate Photolithography layer, CT means PC cut Photolithography layer, CA and CC mean source/drain open Photolithography layer.

Therefore, a first FET is presented including a first device layer and a second FET is presented including a second device layer, where the first device layer has a stepped portion (or shifted or tapered configuration) with respect to the second device layer. An electrical connection is made between a gate of the first FET and a gate of the second FET at the stepped portion of the first device layer. The first FET is stacked over the second FET. The second device layer is larger than the first device layer. The first FET is a p-type FET and the second FET is an n-type FET. In one embodiment, the gate of the first FET is positioned above the first device layer having a stepped portion. In other embodiments, the gate of the first FET is positioned above both the first and second device layers.

FIG. 3 is a cross-sectional view of the semiconductor structure of FIG. 2 depicting the first FET and the second FET of the stacked and stepped FET configuration, in accordance with an embodiment of the present invention.

FIG. 3 is a cross-sectional view along axis “X” depicting the third PFET 14 (P3) and the fourth PFET 16 (P4), as well as the first NFET 20 (N1), the second NFET 22 (N2), the third NFET 24 (N3), and the fourth NFET 26 (N4). The top device layer 30T extends over the third PFET 14 (P3) and the fourth PFET 16 (P4). In particular, the section 34 of the top device layer 30T extends over the third PFET 14 (P3) and the fourth PFET 16 (P4). The bottom device layer 40 extends over the first NFET 20 (N1), the second NFET 22 (N2), the third NFET 24 (N3), and the fourth NFET 26 (N4). The via 60 extends from the circuit input pin 50 (“S”) to the second NFET 22 (N2) and the via 62 extends from the circuit input pin 50 (“S”) to the third PFET 14 (P3).

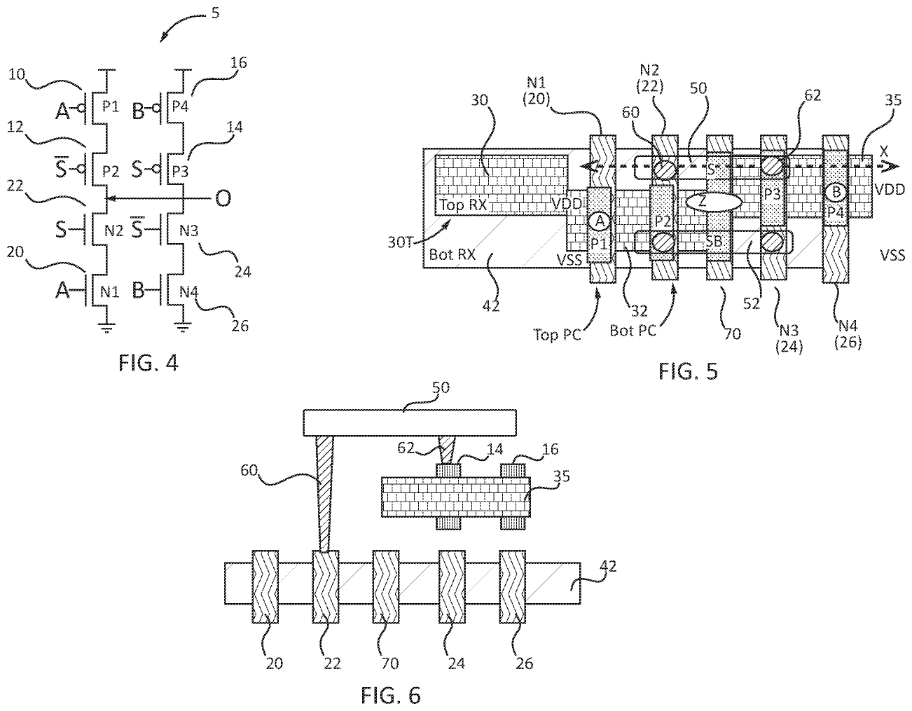

FIG. 4 is the circuit diagram of the stacked FET, in accordance with an embodiment of the present invention.

The circuit 5 depicts an NFET circuit portion including the first NFET 20 (N1), the second NFET 22 (N2), the third NFET 24 (N3), and the fourth NFET 26 (N4). The circuit 5 further depicts a PFET circuit portion including the first PFET 10 (P1), the second PFET 12 (P2), the third PFET 14 (P3), and the fourth PFET 16 (P4). The PFET portion is stacked over the NFET portion. The PFET portion can be in a stepped relationship or tapered relationship with respect to the NFET portion.

FIG. 5 is a top view of a semiconductor structure where the top FET of the stacked and stepped FET configuration includes floating gates, in accordance with an embodiment of the present invention.

The top view depicts the top device layer 30T having multiple sections 30, 32, 35 and a bottom device layer 42. The top device layer 30T can be referred to as a first device layer and the bottom device layer 42 can be referred to as a second device layer. The multiple sections 30, 32, 35 of the top device layer 30T can be advantageously shifted and/or tapered and/or offset from each other. The section 35 of the top device layer 30T is bigger than or larger than or occupies a greater space than the sections 30, 32. Moreover, the bottom device layer 42 is enlarged to accommodate the first NFET 20 (N1), the second NFET 22 (N2), the third NFET 24 (N3), and the fourth NFET 26 (N4), as well as the floating gate 70. Thus, the bottom device layer 42 of FIG. 5 is greater than or larger than or occupies a greater space than the bottom device layer 40 of FIG. 2. The floating gate 70 is advantageously vertically aligned with the stepped portion of the top device layer 30T.

The p-type transistors are shown stacked over the n-type transistors. For example, the first PFET 10 (P1) is stacked over the first NFET 20 (N1), the second PFET 12 (P2) is stacked over the second NFET 22 (N2), the third NFET 24 (N3) is stacked over the third PFET 14 (P3), and the fourth NFET 26 (N4) is stacked over the fourth PFET 16 (P4). The device gates “top PC” and “bottom PC” are also shown. The shifted or tapered device layer is advantageously shifted or tapered between the device gates or “PC.” An electrical connection is advantageously made from the bottom gate to the top gate at the shifted or tapered device layer. A floating gate 70 is positioned between the PFETs and the NFETs. In one example, the floating gate 70 is shown between the second NFET 22 (N2) and the third NFET 24 (N3), and between the second PFET 12 (P2) and the third PFET 14 (P3).

Letters “A” and “B” represent circuit input pins, whereas letter “Z” represents a circuit output pin. The circuit output pin “Z” is positioned over the floating gate 70.

The circuit input pin 50 is represented as “S” and the circuit input pin 52 is represented as “SB.” “S” stands for “Select” and “SB” stands for “Select Bar.” The circuit input pin 50 extends over the floating gate 70. The vias 60, 62 are shown connecting the circuit input pin 50 to the second NFET 22 (N2) and the third PFET 14 (P3).

FIG. 6 is a cross-sectional view of the semiconductor structure of FIG. 5 depicting the floating gates of the top FET, in accordance with an embodiment of the present invention.

FIG. 6 is a cross-sectional view along axis “X” depicting the third PFET 14 (P3) and the fourth PFET 16 (P4), as well as the first NFET 20 (N1), the second NFET 22 (N2), the third NFET 24 (N3), and the fourth NFET 26 (N4). The top device layer 30T extends over the third PFET 14 (P3) and the fourth PFET 16 (P4). In particular, the section 35 of the top device layer 30T extends over the third PFET 14 (P3) and the fourth PFET 16 (P4). The bottom device layer 42 extends over the first NFET 20 (N1), the second NFET 22 (N2), the third NFET 24 (N3), and the fourth NFET 26 (N4). The via 60 extends from the circuit input pin 50 (“S”) to the second NFET 22 (N2) and the via 62 extends from the circuit input pin 50 (“S”) to the third PFET 14 (P3).

The section 35 of the top device layer 30T extends to the floating gate 70 positioned between the second NFET 22 (N2) and the third NFET 24 (N3). Thus, the section 35 is elongated or enlarged to extend to the floating gate 70.

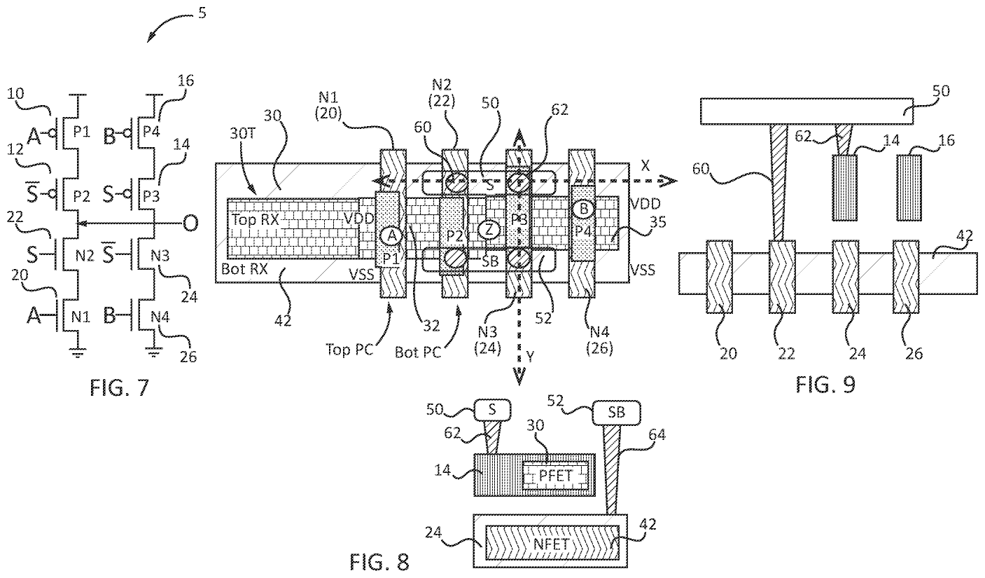

FIG. 7 is the circuit diagram of the stacked FET, in accordance with an embodiment of the present invention.

The circuit 5 depicts an NFET circuit portion including the first NFET 20 (N1), the second NFET 22 (N2), the third NFET 24 (N3), and the fourth NFET 26 (N4). The circuit 5 further depicts a PFET circuit portion including the first PFET 10 (P1), the second PFET 12 (P2), the third PFET 14 (P3), and the fourth PFET 16 (P4). The PFET portion is stacked over the NFET portion. The PFET portion can be in a stepped relationship or tapered relationship with respect to the NFET portion.

FIG. 8 is a top view of a semiconductor structure where the stacked and stepped FET configuration includes double step stacked FETs, in accordance with an embodiment of the present invention.

The top view depicts the top device layer 30T having multiple sections 30, 32, 35 and a bottom device layer 42. The top device layer 30T can be referred to as a first device layer and the bottom device layer 42 can be referred to as a second device layer. The multiple sections 30, 32, 35 of the top device layer 30T can be aligned with each other (in contrast to the configurations of FIGS. 2 and 5). This can be referred to as a double step stacked FET configuration. The top device layer 30T is substantially or generally centered with respect to the bottom device layer 42.

The p-type transistors are shown stacked over the n-type transistors. For example, the first PFET 10 (P1) is stacked over the first NFET 20 (N1), the second PFET 12 (P2) is stacked over the second NFET 22 (N2), the third NFET 24 (N3) is stacked over the third PFET 14 (P3), and the fourth NFET 26 (N4) is stacked over the fourth PFET 16 (P4). The device gates “top PC” and “bottom PC” are also shown.

Letters “A” and “B” represent circuit input pins, whereas letter “Z” represents a circuit output pin. The circuit input pin 50 is represented as “S” and the circuit input pin 52 is represented as “SB.” “S” stands for “Select” and “SB” stands for “Select Bar.” The vias 60, 62 are shown connecting the circuit input pin 50 to the second NFET 22 (N2) and the third PFET 14 (P3).

A cross-sectional view along the Y-axis is also shown, which depicts the circuit input pin 50 connected to the third PFET 14 (P3) by the via 62 and the circuit input pin 52 connected to the third NFET 24 (N3) by the via 64.

FIG. 9 is a cross-sectional view of the semiconductor structure of FIG. 8 depicting the first FET and the second FET of the stacked and stepped FET configuration, in accordance with an embodiment of the present invention.

FIG. 9 is a cross-sectional view along axis “X” depicting the third PFET 14 (P3) and the fourth PFET 16 (P4), as well as the first NFET 20 (N1), the second NFET 22 (N2), the third NFET 24 (N3), and the fourth NFET 26 (N4). The bottom device layer 42 extends over the first NFET 20 (N1), the second NFET 22 (N2), the third NFET 24 (N3), and the fourth NFET 26 (N4). The via 60 extends from the circuit input pin 50 (“S”) to the second NFET 22 (N2) and the via 62 extends from the circuit input pin 50 (“S”) to the third PFET 14 (P3). The top device layer 30T is not visible in contrast to FIGS. 3 and 6.

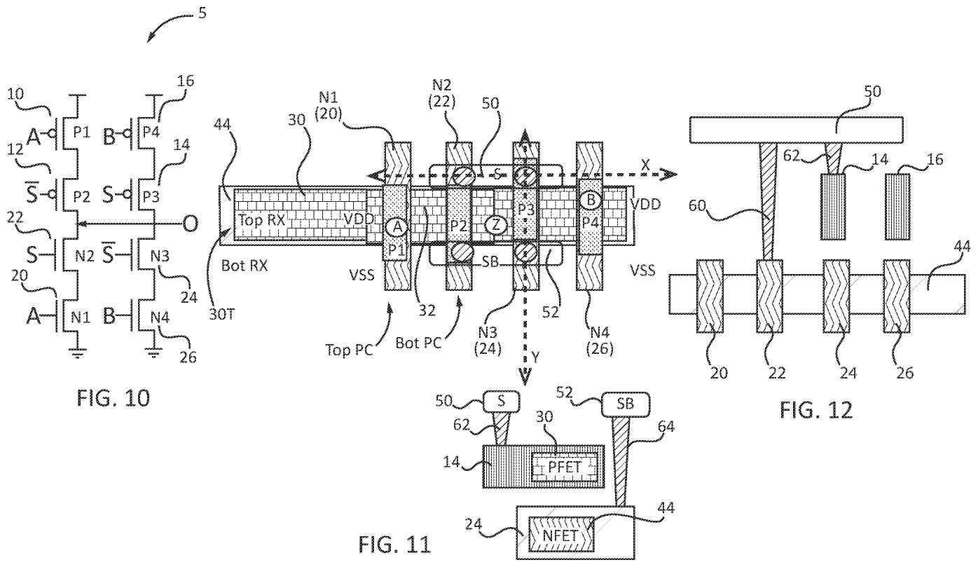

FIG. 10 is the circuit diagram of the stacked FET, in accordance with an embodiment of the present invention.

The circuit 5 depicts an NFET circuit portion including the first NFET 20 (N1), the second NFET 22 (N2), the third NFET 24 (N3), and the fourth NFET 26 (N4). The circuit 5 further depicts a PFET circuit portion including the first PFET 10 (P1), the second PFET 12 (P2), the third PFET 14 (P3), and the fourth PFET 16 (P4). The PFET portion is stacked over the NFET portion. The PFET portion can be in a stepped relationship or tapered relationship with respect to the NFET portion.

FIG. 11 is a top view of a semiconductor structure where the stacked and stepped FET configuration includes double step stacked FETs with a smaller bottom transistor, in accordance with an embodiment of the present invention.

The top view depicts the top device layer 30T having multiple sections 30, 32, 35 and a bottom device layer 44. The top device layer 30T can be referred to as a first device layer and the bottom device layer 44 can be referred to as a second device layer. The multiple sections 30, 32, 35 of the top device layer 30T can be aligned with each other (in contrast to the configurations of FIGS. 2 and 5). This can be referred to as a double step stacked FET configuration. Moreover, the bottom device layer 44 is thinner than the bottom device layer 42 of FIGS. 2 and 3. The top device layer 30T almost entirely overlaps the bottom device layer 44.

The p-type transistors are shown stacked over the n-type transistors. For example, the first PFET 10 (P1) is stacked over the first NFET 20 (N1), the second PFET 12 (P2) is stacked over the second NFET 22 (N2), the third NFET 24 (N3) is stacked over the third PFET 14 (P3), and the fourth NFET 26 (N4) is stacked over the fourth PFET 16 (P4). The device gates “top PC” and “bottom PC” are also shown.

Letters “A” and “B” represent circuit input pins, whereas letter “Z” represents a circuit output pin. The circuit input pin 50 is represented as “S” and the circuit input pin 52 is represented as “SB.” “S” stands for “Select” and “SB” stands for “Select Bar.” The vias 60, 62 are shown connecting the circuit input pin 50 to the second NFET 22 (N2) and the third PFET 14 (P3).

A cross-sectional view along the Y-axis is also shown, which depicts the circuit input pin 50 connected to the third PFET 14 (P3) by the via 62 and the circuit input pin 52 connected to the third NFET 24 (N3) by the via 64. The difference with FIG. 8 is that the bottom device layer 44 is smaller such that a larger portion of the first NFET 20 (N1), the second NFET 22 (N2), the third NFET 24 (N3), and the fourth NFET 26 (N4) is exposed. Additionally, a larger portion of the third PFET 14 (P3) and the fourth PFET 16 (P4) is exposed.

FIG. 12 is a cross-sectional view of the semiconductor structure of FIG. 11 depicting the first FET and the second FET of the stacked and stepped FET configuration with the smaller bottom FET, in accordance with an embodiment of the present invention.

FIG. 12 is a cross-sectional view along axis “X” depicting the third PFET 14 (P3) and the fourth PFET 16 (P4), as well as the first NFET 20 (N1), the second NFET 22 (N2), the third NFET 24 (N3), and the fourth NFET 26 (N4). The bottom device layer 44 extends over the first NFET 20 (N1), the second NFET 22 (N2), the third NFET 24 (N3), and the fourth NFET 26 (N4). The via 60 extends from the circuit input pin 50 (“S”) to the second NFET 22 (N2) and the via 62 extends from the circuit input pin 50 (“S”) to the third PFET 14 (P3). The top device layer 30T is not visible in contrast to FIGS. 3 and 6.

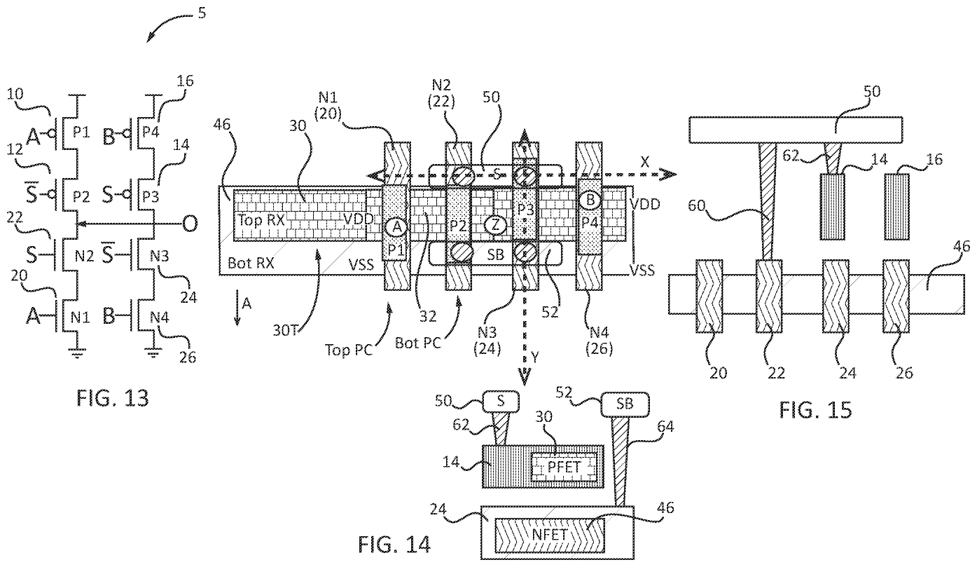

FIG. 13 is the circuit diagram of the stacked FET, in accordance with an embodiment of the present invention.

The circuit 5 depicts an NFET circuit portion including the first NFET 20 (N1), the second NFET 22 (N2), the third NFET 24 (N3), and the fourth NFET 26 (N4). The circuit 5 further depicts a PFET circuit portion including the first PFET 10 (P1), the second PFET 12 (P2), the third PFET 14 (P3), and the fourth PFET 16 (P4). The PFET portion is stacked over the NFET portion. The PFET portion can advantageously be in a stepped relationship or tapered relationship with respect to the NFET portion.

FIG. 14 is a top view of a semiconductor structure where the stacked and stepped FET configuration includes double step stacked FETs with a larger bottom transistor, in accordance with an embodiment of the present invention.

The top view depicts the top device layer 30T having multiple sections 30, 32, 35 and a bottom device layer 46. The top device layer 30T can be referred to as a first device layer and the bottom device layer 46 can be referred to as a second device layer. The multiple sections 30, 32, 35 of the top device layer 30T can be aligned with each other (in contrast to the configurations of FIGS. 2 and 5). This can be referred to as a double step stacked FET configuration. Moreover, the bottom device layer 46 extends along direction “A,” which results in the top device layer 30T not being centered with respect to the bottom device layer 46. Thus, the first device layer is positioned adjacent the second device layer such that a surface of the first device layer is horizontally aligned with a surface of the second device layer.

The p-type transistors are shown stacked over the n-type transistors. For example, the first PFET 10 (P1) is stacked over the first NFET 20 (N1), the second PFET 12 (P2) is stacked over the second NFET 22 (N2), the third NFET 24 (N3) is stacked over the third PFET 14 (P3), and the fourth NFET 26 (N4) is stacked over the fourth PFET 16 (P4). The device gates “top PC” and “bottom PC” are also shown.

Letters “A” and “B” represent circuit input pins, whereas letter “Z” represents a circuit output pin. The circuit input pin 50 is represented as “S” and the circuit input pin 52 is represented as “SB.” “S” stands for “Select” and “SB” stands for “Select Bar.” The vias 60, 62 are shown connecting the circuit input pin 50 to the second NFET 22 (N2) and the third PFET 14 (P3).

A cross-sectional view along the Y-axis is also shown, which depicts the circuit input pin 50 connected to the third PFET 14 (P3) by the via 62 and the circuit input pin 52 connected to the third NFET 24 (N3) by the via 64. The difference with FIG. 11 is that the bottom device layer 46 is advantageously larger than the bottom device layer 44 and off-centered from the top device layer 30T.

FIG. 15 is a cross-sectional view of the semiconductor structure of FIG. 14 depicting the first FET and the second FET of the stacked and stepped FET configuration with the larger bottom FET, in accordance with an embodiment of the present invention.

FIG. 15 is a cross-sectional view along axis “X” depicting the third PFET 14 (P3) and the fourth PFET 16 (P4), as well as the first NFET 20 (N1), the second NFET 22 (N2), the third NFET 24 (N3), and the fourth NFET 26 (N4). The bottom device layer 46 extends over the first NFET 20 (N1), the second NFET 22 (N2), the third NFET 24 (N3), and the fourth NFET 26 (N4). The via 60 extends from the circuit input pin 50 (“S”) to the second NFET 22 (N2) and the via 62 extends from the circuit input pin 50 (“S”) to the third PFET 14 (P3). The top device layer 30T is not visible in contrast to FIGS. 3 and 6.

In conclusion, the exemplary embodiments of the present invention present methods and devices for constructing a latch cross couple for a stacked and stepped FET. The stacked FET includes a first device layer and a second device layer, where one of the device layers is advantageously shifted or tapered or stepped with respect to the other device layer. The shifted or tapered device layer is advantageously shifted or tapered between the device gates or “PC.” An electrical connection is advantageously made from the bottom gate to the top gate at the shifted or tapered device layer. A floating gate can also be employed over the shifted or tapered device layer. In other embodiments, a double step stacked FET is advantageously employed. Moreover, one of the device layers advantageously has a greater size or is larger than the other device layer.

Regarding FIGS. 1-15, deposition is any process that grows, coats, or otherwise transfers a material onto a wafer. Available technologies include, but are not limited to, thermal oxidation, physical vapor deposition (PVD), chemical vapor deposition (CVD), electrochemical deposition (ECD), molecular beam epitaxy (MBE) and more recently, atomic layer deposition (ALD) among others. As used herein, “depositing” can include any now known or later developed techniques appropriate for the material to be deposited including but not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metal-organic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

The term “processing” as used herein includes deposition of material or photoresist, patterning, exposure, development, etching, cleaning, stripping, implanting, doping, stressing, layering, and/or removal of the material or photoresist as needed in forming a described structure.

It is to be understood that the present invention will be described in terms of a given illustrative architecture; however, other architectures, structures, substrate materials and process features and steps/blocks can be varied within the scope of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical mechanisms (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which usually include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present embodiments. The compounds with additional elements will be referred to herein as alloys.

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of methods and structures providing for constructing a latch cross couple for stacked and stepped FETs (which are intended to be illustrative and not limiting), it is noted that modifications and variations can be made by persons skilled in the art in light of the above teachings. It is therefore to be understood that changes may be made in the particular embodiments described which are within the scope of the invention as outlined by the appended claims. Having thus described aspects of the invention, with the details and particularity required by the patent laws, what is claimed and desired protected by Letters Patent is set forth in the appended claims.

1. A semiconductor structure comprising:
a first field effect transistor (FET) including a first device layer;
a second FET including a second device layer, where the first device layer has a stepped portion with respect to the second device layer; and
an electrical connection between a gate of the first FET and a gate of the second FET at the stepped portion of the first device layer.

2. The semiconductor structure of claim 1, wherein the first FET is stacked over the second FET.

3. The semiconductor structure of claim 1, wherein the second device layer is larger than the first device layer.

4. The semiconductor structure of claim 1, wherein the first FET is a p-type FET and the second FET is an n-type FET.

5. The semiconductor structure of claim 1, wherein the gate of the first FET is positioned above the first device layer having the stepped portion.

6. The semiconductor structure of claim 1, wherein the gate of the first FET is positioned above both the first and second device layers.

7. The semiconductor structure of claim 1, wherein the second FET includes a floating gate.

8. The semiconductor structure of claim 7, wherein the floating gate is vertically aligned with the stepped portion of the first device layer.

9. A semiconductor structure comprising:
a first field effect transistor (FET) including a first device layer;
a second FET including a second device layer; and
an electrical connection between a gate of the first FET and a gate of the second FET at a stepped portion of the first device layer.

10. The semiconductor structure of claim 9, wherein the first FET is stacked over the second FET.

11. The semiconductor structure of claim 9, wherein the second device layer is larger than the first device layer.

12. The semiconductor structure of claim 11, wherein the first device layer is centered with respect to the second device layer.

13. The semiconductor structure of claim 11, wherein the first device layer is positioned adjacent the second device layer such that a surface of the first device layer is horizontally aligned with a surface of the second device layer.

14. The semiconductor structure of claim 9, wherein the first device layer generally overlaps the second device layer.

15. The semiconductor structure of claim 9, wherein the gate of the first FET is positioned above the first device layer having a doubled stepped configuration.

16. The semiconductor structure of claim 9, wherein the gate of the first FET is positioned above both the first and second device layers.

17. A semiconductor structure comprising:
a first field effect transistor (FET) including a first device layer;
a second FET including a second device layer, where the second device layer is larger than the first device layer; and
an electrical connection between a gate of the first FET and a gate of the second FET at a stepped portion of the first device layer.

18. The semiconductor structure of claim 17, wherein the first device layer has a stepped portion with respect to the second device layer.

19. The semiconductor structure of claim 17, wherein the first FET is stacked over the second FET.

20. The semiconductor structure of claim 17, wherein the gate of the first FET is positioned above the first device layer having a stepped portion.
